(19) United States
(12) Patent Application Publication
(10) Pub. No.: US 2026/0354080 A1
(43) Pub. Date: Nov. 5, 2026

(54) LOW PRESSURE exhaust system for processing chamber

(71) Applicant: Applied Materials, Inc., Santa Clara, CA (US)

(72) Inventors: Eric DAVEY, Mountain View, CA (US); Abbas RASTEGAR, Schenectady, NY (US); Lei ZHANG, Santa Clara, CA (US); Liurui LI, Santa Clara, CA (US); Govindarajasekhar SINGU, Santa Clara, CA (US); Borui XIA, San Jose, CA (US)

(21) Appl. No.: 19/661,046

(22) Filed: Apr. 28, 2026

Related U.S. Application Data
(60) Provisional application No. 63/805,063, filed on May 13, 2025.
(60) Provisional application No. 63/797,813, filed on Apr. 30, 2025.

(51) Int. Cl. H10P 72/00

(52) U.S. Cl. CPC H10P 72/0421

(57) ABSTRACT

Embodiments of the present invention generally relate a low pressure exhaust system for a semi-conductor processing chamber, such as a low pressure epi preclean etch chamber, and related methods. In one or more embodiments, a processing system includes a processing chamber comprising a processing volume. A vacuum pump is fluidly connected to the processing volume. A turbo assembly is fluidly connected to the processing volume. The turbo assembly includes a turbo throttle valve, a turbo pump, and a turbo gate valve.

### CROSS-REFERENCE TO RELATED APPLICATIONS

This application claims priority to United States Provisional Patent Application 63/805,063, filed on May. 13, 2025, and United States Provisional Patent Application 63/797,813, filed on Apr. 30, 2025, the contents of which are incorporated herein by reference.

### BACKGROUND

### Field

Embodiments of the present invention generally relate a low pressure exhaust system for a semi-conductor processing chamber, such as a low pressure epi preclean etch chamber, and related methods.

### Description of the Related Art

In semiconductor device fabrication, a substrate may include one or more oxide films formed on its surface as part of various processing steps. These oxide films often serve as insulating layers, hard masks, or sacrificial materials and typically need to be selectively removed during subsequent etching processes. To achieve this, an etchant gas is introduced to selectively remove the oxide film without affecting other materials on the substrate.

However, etching processes sometimes exhibit poor etch selectivity, resulting in the unintended removal or damage of semiconductor films formed over the substrate alongside the oxide film. This can compromise device integrity and reduce overall manufacturing yield.

Therefore, there is a need for an improved etching system and associated methods capable of removing oxide films with higher selectivity, thereby preserving the structural and functional integrity of adjacent semiconductor materials.

### SUMMARY

Embodiments of the present invention generally relate a low pressure exhaust system for a semi-conductor processing chamber, such as a low pressure epi preclean etch chamber, and related methods.

In one or more embodiments, a processing system includes a processing chamber comprising a processing volume. A vacuum pump is fluidly connected to the processing volume. A turbo assembly is fluidly connected to the processing volume. The turbo assembly includes a turbo throttle valve, a turbo pump, and a turbo gate valve.

In one or more embodiments, a method of substrate processing includes performing an exhaust operation comprising flowing one or more gases within a processing volume of a processing chamber through an exhaust line to a vacuum pump. The method further includes closing an exhaust gate valve disposed within the exhaust line and opening a turbo gate valve disposed within a turbo assembly in fluid communication with the processing volume. The method further includes opening a turbo throttle valve disposed within the turbo assembly and performing a turbo operation comprising flowing the one or more gases from the processing volume though the turbo assembly to the vacuum pump.

In one or more embodiments, a controller includes instructions that cause a plurality of operations to be conducted. The plurality of operations include performing an exhaust operation including flowing one or more gases within a processing volume of a processing chamber through an exhaust line to a vacuum pump. The plurality of operations further include closing an exhaust gate valve disposed within the exhaust line and opening a turbo gate valve disposed within a turbo assembly in fluid communication with the processing volume. The plurality of operations further include opening a turbo throttle valve disposed within the turbo assembly and performing a turbo operation including flowing the one or more gases from the processing volume though the turbo assembly to the vacuum pump.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a partial schematic cross sectional side view of a processing system, according to one or more embodiments.

FIG. 2 is a schematic cross sectional view of a turbo assembly fluidly connected to a processing chamber, according to one or more embodiments.

FIG. 3 is a schematic block diagram of a method of substrate processing, according to one or more embodiments.

FIG. 4 is a schematic representation of a graph, according to one or more embodiments.

FIG. 5 is a schematic plan view of a system, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate a low pressure exhaust system for a semi-conductor processing chamber and related methods. In one or more embodiments, the processing chamber is a pre-clean chamber. The pre-clean chamber includes an exhaust system. The exhaust system includes a vacuum pump and a turbo pump. During a turbo operation the turbo pump exhausts one or more process gases within the processing volume of the processing chamber. The turbo pump is configured to lower the pressure within the processing volume to 1 Torr or less such as 500 mTorr or less, such as 100 mTorr.

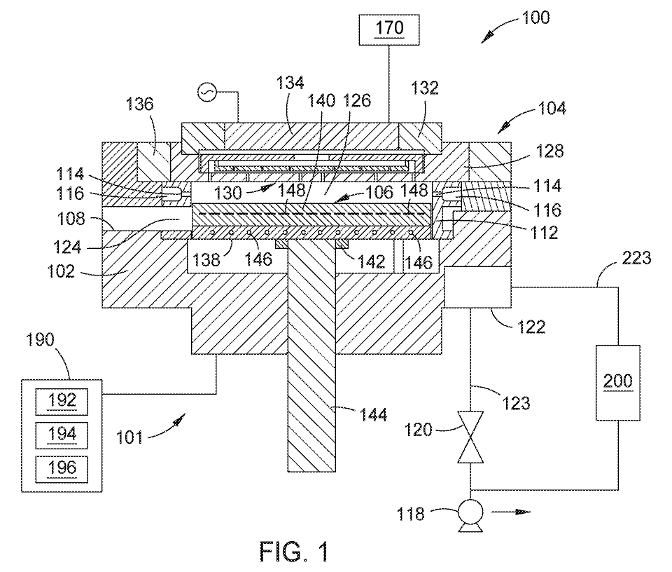

FIG. 1 is a partial schematic cross sectional side view of a processing system 101, according to one or more embodiments. The processing system 101 includes a processing chamber 100, and the processing chamber 100 includes a chamber body 102, a lid assembly 104, and a substrate support 106. In one or more embodiments, the substrate support 106 includes a pedestal. In one or more embodiments, the substrate support 106 includes a ring. The lid assembly 104 is disposed at an upper end of the chamber body 102, and the substrate support 106 is at least partially disposed within the chamber body 102. The processing chamber 100 and the associated hardware can be formed from one or more process-compatible materials, such as aluminum.

The chamber body 102 includes a slit valve opening 108 formed in a sidewall thereof to provide access to the interior of the processing chamber 100. The slit valve opening 108 is selectively opened and closed via a slit valve (not shown) to allow access to the interior of the chamber body 102 by a handling robot. A substrate can be transported in and out of the processing chamber 100 through the slit valve opening 108 to an adjacent transfer chamber and/or load-lock chamber, or another chamber within a cluster tool.

The chamber body 102 also includes a liner 112 that surrounds the substrate support 106. The liner 112 can be removable for servicing and cleaning. The liner 112 can be made of a metal such as aluminum or stainless steel, silicon carbide (SiC), or a ceramic material. The liner 112 can be any process compatible material. The liner 112 can be bead blasted to increase the adhesion of any material deposited thereon, thereby preventing flaking of material which results in contamination of the processing chamber 100. In one or more embodiments, the liner 112 includes one or more apertures 114 and a pumping channel 116 formed therein that is in fluid communication with a vacuum system. The apertures 114 can provide a flow path for gases into the pumping channel 116, which provides an egress for the gases within the processing chamber 100.

The vacuum system can include a vacuum pump 118 and a throttle valve 120 to regulate flow of gases through the processing chamber 100. The vacuum pump 118 and the throttle valve 120 are disposed along an exhaust line 123. The vacuum pump 118 is coupled to a vacuum port 122 disposed on the chamber body 102 and therefore, in fluid communication with the pumping channel 116 formed in the liner 112. An aperture 124 is aligned with the slit valve opening 108 disposed on a side wall of the chamber body 102. The aperture 124 is formed within the liner 112 to allow entry and egress of substrates to/from the chamber body 102. The terms “gas” and “gases” are used interchangeably, unless otherwise noted, and can refer to one or more precursors, reactants, catalysts, carrier, purge, cleaning, etching, combinations thereof, as well as any other fluid introduced into the chamber body 102.

The apertures 114 can allow the pumping channel 116 to be in fluid communication with a processing volume 126 within the chamber body 102. The processing volume 126 can be defined by a lower surface of the lid assembly 104 and an upper surface of the substrate support 106, and can be surrounded by the liner 112. The apertures 114 may be uniformly sized and evenly spaced about the liner 112. Any number, position, size or shape of apertures may be used, and the number, position, size or shape of apertures can vary depending on the flow pattern of gas across the substrate receiving surface as is discussed in more detail below. In addition, the size, number and position of the apertures 114 can be configured to achieve uniform flow of gases exiting the processing chamber 100. The aperture size and location may be configured to provide rapid or high capacity pumping to facilitate a rapid exhaust of gas from the processing chamber 100. For example, the number and size of apertures 114 in closer proximity to the vacuum port 122 may be smaller than the size of apertures 114 positioned farther away from the vacuum port 122.

In operation, one or more gases exiting the processing chamber 100 flow through the apertures 114 formed through the liner 112, and flow into the pumping channel 116. The gas then flows within the pumping channel 116 and through ports into a vacuum channel and exits the vacuum channel through the vacuum port 122 into the vacuum pump 118.

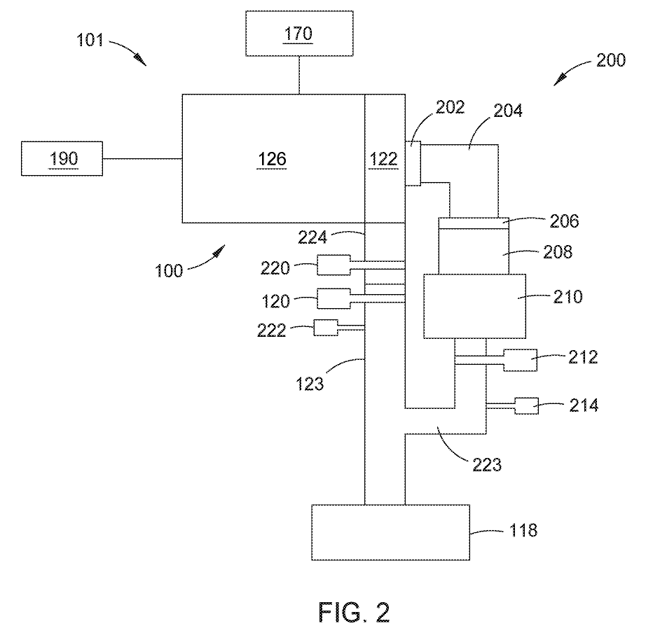

In one or more embodiments, a turbo assembly 200 is fluidly connected to the vacuum port 122. The turbo assembly 200 is disposed along a turbo line 223. The turbo line 223 is fluidly connected to the exhaust line 123 and the vacuum pump 118. In one or more embodiments, the turbo line 223 exhausts into the exhaust line 123 downstream of the throttle valve 120. During a turbo operation the gases within the processing volume 126 are pumped through the vacuum port 122 into the turbo line 223. The gases are pumped through the turbo line 223 into the turbo assembly 200. The gases are exhausted by the turbo assembly 200 to the exhaust line 123 where the gases are exhausted by the vacuum pump 118. The turbo assembly 200 is described in greater detail in FIG. 2.

In one or more embodiments, one or more gas sources 170 are coupled to the processing chamber 100. The one or more gases sources are configured to flow one or more gases into the processing volume 126. The one or more gases include one or more precursors, reactants, catalysts, carrier, purge, cleaning, etching, combinations thereof, as well as any other fluid introduced into the processing volume 126. In one or more embodiments, the one or more gases include hydrogen fluoride (HF) gas ammonia (NH₃) gas, argon (Ar) gas, or a combination thereof.

The lid assembly 104 includes a number of components stacked on top of one another, as shown in FIG. 1. In one or more embodiments, the lid assembly 104 includes a lid rim 128, a gas delivery assembly 130, and a top plate 132. The gas delivery assembly 130 is coupled to the lid rim 128 (such as an upper surface of the lid rim 128) and can be arranged to reduce thermal contact with the lid rim 128. The components of the lid assembly 104 can be constructed of a material having a high thermal conductivity and low thermal resistance, such as an aluminum alloy with a highly finished surface for example. The thermal resistance of the components of the lid assembly 104 can be less than about 5x10⁻⁴ m² K/W. The lid rim 128 can hold the weight of the components making up the lid assembly 104 and can be coupled to an upper surface of the chamber body 102 via a hinge assembly to provide access to the internal chamber components, such as the substrate support 106 for example.

The lid assembly 104 includes an electrode 134 to generate a plasma of reactive species within the processing volume 126. In one or more embodiments, the electrode 134 is supported on the top plate 132 and is electrically isolated from the top plate 132. For example, an isolator ring 136 can be disposed about a lower portion of the electrode 134 to separate the electrode 134 from the top plate 132. The isolator ring 136 can be made from aluminum oxide or any other insulative and process compatible material.

In one or more embodiments, the electrode 134 is coupled to a power source and the gas delivery assembly 130 is connected to ground (e.g., the gas delivery assembly 130 can serve as an electrode). Accordingly, a plasma of one or more process gases can be generated in the processing volume 126 and/or within the gas delivery assembly 130.

Any power source capable of activating the gases into reactive species and maintaining the plasma of reactive species may be used. For example, radio frequency (RF), direct current (DC), and/or microwave (MW) based power discharge techniques may be used. The activation may also be generated by a thermally based technique, a gas breakdown technique, a high intensity light source (e.g., UV energy), and/or exposure to an x-ray source. A remote activation source may be used, such as a remote plasma generator, to generate a plasma of reactive species which are then delivered into the processing chamber 100. While the processing chamber 100 is shown and described as a plasma processing chamber, the substrate support 106 as described herein may be utilized in other chambers that are not utilized for plasma processing, such as chemical vapor deposition (CVD) processes.

The substrate support 106 includes a cooling base 138. The cooling base 138 is coupled to a support member 140 and a flange 142 of a stem 144. The cooling base 138 includes a plurality of cooling channels 146 formed therein for flowing a coolant. The support member 140 includes a plurality of heating elements 148. The heating elements 148 can function as a multi-zone heater.

In one or more embodiments, a controller 190 is coupled to the processing chamber 100, the turbo assembly 200, or a combination thereof. The controller 190 is configured to control one or more components of the processing system 101. In operation, the controller 190 enables data collection and feedback from one or more sensors/gauges within the processing system 101 in order to coordinate performance of the processing system 101.

The controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular processing chamber) as, for example, a software routine. When the computer instruction code is executed by the CPU 192, the CPU 192 controls one or more components within the processing system 101 to perform processes in accordance with the various methods (such as the method 300 described below).

FIG. 2 is a schematic cross sectional view of the turbo assembly 200 fluidly connected to the processing chamber 100, according to one or more embodiments. The turbo assembly 200 includes a turbo inlet 202, an elbow pipe 204, a throttle valve adaptor 206, a turbo throttle valve 208, a turbo pump 210, a turbo gate valve 212, and a first pressure gauge 214.

The turbo inlet 202 is fluidly connected to the vacuum port 122. The elbow pipe 204 is coupled to the turbo inlet 202. The elbow pipe 204 extends between the turbo inlet 202 and the throttle valve adaptor 206. The throttle valve adaptor 206 is configured to fluidly connect the elbow pipe 204 with the turbo throttle valve 208. The turbo throttle valve 208 is configured to control the flow rate of the gases flowing into the turbo pump 210 by adjusting the size of the opening through which the gas passes. When the turbo throttle valve 208 is partially open, it restricts the flow of the gases, reducing the amount of gas that reaches the turbo pump 210. Conversely, fully opening the turbo throttle valve 208 allows the gas to flow at a higher rate through the turbo pump 210. By controlling the size of the opening of the turbo throttle valve 208, the turbo throttle valve 208 regulates the pressure and the flow rate of the gas within the turbo pump 210, ensuring optimal performance and protecting the turbo pump 210 from overload.

The turbo pump 210 is fluidly connected to the turbo throttle valve 208. In one or more embodiments, the turbo pump 210 has a pumping speed of about 1.6 kiloliters per second (kl/s). During a turbo operation, the turbo pump 210 has a rotational speed of about X rpm to about Y rpm. In one or more embodiments, during the turbo operation, the turbo pump 210 pumps the gas at a flow rate less than or equal to about 3 standard liters per min (SLM) such as about 2.5 SLM. In one or more embodiments, during the turbo operation, the turbo pump 210 pumps the gas for 100 seconds or less, such as 90 seconds or sess. During the turbo operation the turbo pump reduces the pressure within the processing volume 126 to about 1 Torr or less, such as about 500 mTorr or less. Reducing the pressure within the processing volume 126 improves the etch selectivity of the one or more etchant gases during an etching process. In addition, reducing the pressure within the processing volume 126 may reduce the amount of water vapor within the processing volume 126 during an etching process. In one or more embodiments, the water vapor within the processing volume 126 may contaminate the substrate by reabsorbing onto a substrate and reoxidating one or more films formed over the substrate. Furthermore, decreasing the pressure within the processing volume 126 may improve the etch conformality, which may lead to improved epitaxial film growth within three dimensional features formed over the substrate..

The turbo assembly 200 further includes the turbo gate valve 212. The turbo gate valve 212 is disposed downstream of the turbo pump 210. The turbo gate valve 212 protects the turbo pump 210 from a pressure back up. In one or more embodiments, during an exhaust operation, the vacuum pump 118 may not properly exhaust the gases flowing through the exhaust line 123, the turbo line 223, or a combination thereof. The vacuum pump 118 not properly exhausting the gases may result in an increase in pressure within the turbo line 223 downstream of the turbo pump 210. If there is an increase in pressure downstream of the turbo pump 210, the turbo gate valve 212 is shut in order to prevent the increased pressure from reaching the turbo pump 210. If the turbo pump 210 is exposed to the increased pressure, then the turbo pump 210 could be damaged.

The turbo assembly 200 further includes the first pressure gauge 214. The first pressure gauge 214 is configured to detect the pressure within the turbo line 223 downstream of the turbo pump 210. In one or more embodiments, the pressure detected by the first pressure gauge 214 is sent to the controller 190 as an electronic signal. In one or more embodiments, the controller 190 detects the electronic signal sent by the first pressure gauge 214 and adjusts one or more components within the processing system 101 based on the electronic signal. For example, the controller 190 may open or close the turbo gate valve 212 based on the pressure detected by the first pressure gauge 214.

In one or more embodiments, the exhaust line 123 extends from the vacuum port 122 to the vacuum pump 118. An exhaust inlet 224 fluidly connects the vacuum port 122 to the exhaust line 123. An exhaust gate valve 220, the throttle valve 120, and a second pressure gauge 222 are disposed along the exhaust line 123. The exhaust gate valve 220 can be either opened or closed. In one or more embodiments, during a turbo operation the exhaust gate valve 220 is closed in order to prevent the gas within the vacuum port 122 from exhausting the exhaust line 123. The exhaust line 123 further includes the throttle valve 120 configured to control the flow rate of the gas flowing through the exhaust line 123 during an exhaust operation.

The second pressure gauge 222 is configured to detect the pressure within the exhaust line 123 downstream of the throttle valve 120. In one or more embodiments, the pressure detected by the second pressure gauge 222 is sent to the controller 190 as an electronic signal. In one or more embodiments, the controller 190 detects the electronic signal sent by the second pressure gauge 222 and adjusts one or more components within the processing system 101 based on the electronic signal. For example, the controller 190 may adjust the position of the throttle valve 120 based on the pressure detected by the second pressure gauge 222.

During an exhaust operation the turbo throttle valve 208 and the turbo gate valve 212 are closed in order to prevent one or more gases within the processing volume 126 from flowing through the turbo assembly 200. The exhaust gate valve 220 is open so that the one or more gases flow from the process volume 126 through the exhaust line 123 and into the vacuum pump 118, where the one or more gases are exhausted. The throttle valve 120 controls the flow rate of the one or more gases flowing through the exhaust line 123. In one or more embodiments, the controller 190 is used to control the position of the throttle valve 120. During the exhaust operation the pressure within the process volume is from about 1 Torr to about 10 Torr, such as about 3 Torr.

During a turbo operation the exhaust gate valve 220 is closed to prevent the one or more gases within the processing volume 126 from flowing through exhaust line 123. The turbo throttle valve 208 and the turbo gate valve 212 are at least partially opened so that the one or more gases flow from the process volume 126 through the turbo pump 210 and the turbo line 223. The one or more gases flow from the turbo pump 210 through the turbo line 223 and into the vacuum pump 118 where the one or more gases are exhausted. The turbo throttle valve 208 controls the flow rate of the one or more gases flowing through the turbo pump 210. In one or more embodiments, the controller 190 is used to control the position of the turbo throttle valve 208. During the turbo operation the pressure within the process volume is less than or equal to about 1 Torr, such as less than or equal to 500 mTorr, such as less than or equal to 100 mTorr.

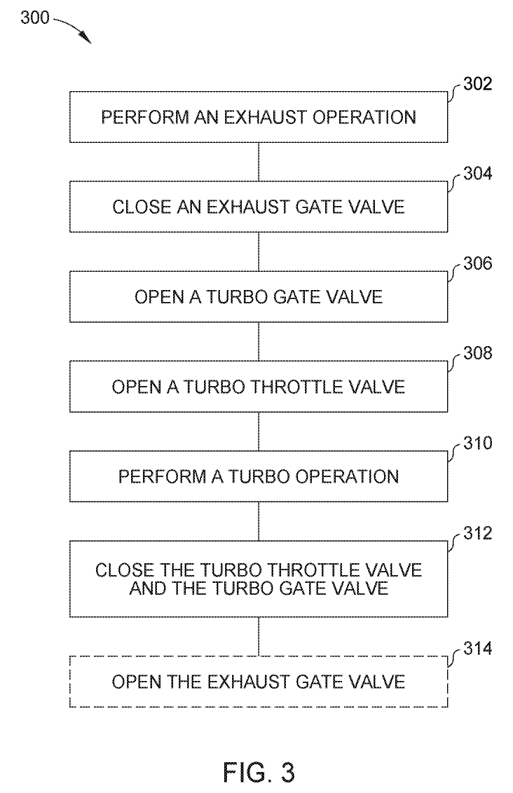

FIG. 3 is a schematic block diagram of a method 300 of substrate processing, according to one or more embodiments. The method 300 may be conducted in the processing system 101. In an exemplary manner, the method 300 is described in relation to the processing system 101 and the turbo assembly 200 of FIGS. 1 and 2. The present disclosure contemplates that other apparatus and/or other compositions can be used for the method 300.

At operation 302, an exhaust operation is performed. During the exhaust operation one or more gases within the processing volume 126 are exhausted from the processing volume 126 through the vacuum port 122 and into the exhaust line 123. The one or more process gases flow through the exhaust line 123 into the vacuum pump 118. In one or more embodiments, the turbo throttle valve 208 and the turbo gate valve 212 are closed in order to prevent one or more gases within the processing volume 126 from flowing through the turbo assembly 200. The exhaust gate valve 220 is open so that the one or more gases flow from the process volume 126 through the exhaust line 123 and into the vacuum pump 118, where the one or more gases are exhausted. The throttle valve 120 controls the flow rate of the one or more gases flowing through the exhaust line 123. In one or more embodiments, the controller 190 is used to control the position of the throttle valve 120. During the exhaust operation the pressure within the process volume is from about 1 Torr to about 10 Torr, such as about 3 Torr. In one or more embodiments, the turbo pump 210 is activated during operation 302.

At operation 304, the exhaust gate valve 220 is closed. After the exhaust gate valve 220 is closed, the one or more gases within the processing volume 126 are prevented from flowing through the exhaust line 123. In one or more embodiments, operation 304 is performed by the controller 190. In one or more embodiments, after the exhaust gate valve 220 is closed, the turbo pump 210 is inspected to determine whether turbo pump 210 is running correctly and free of defects.

At operation 306, the turbo gate valve 212 is opened. In one or more embodiments, operation 306 is performed by the controller 190. In one or more embodiments, after the turbo gate valve 212 is opened, the turbo gate valve 212 is inspected to determine whether turbo gate valve 212 is functioning correctly and free of defects.

At operation 308, the turbo throttle valve 208 is opened. In one or more embodiments, the turbo throttle valve 208 is opened gradually as to prevent the turbo pump 210 from being damaged. In one or more embodiments, the turbo throttle valve 208 is opened to a first position. The first position causes the one or more gases flowing through the turbo throttle valve 208 to flow at a first flow rate. The first flow rate is configured to prevent the turbo pump 210 from being damaged. If the first flow rate is to high, then the change in pressure of the of the one or more gases flowing through the turbo pump 210 results in the turbo pump 210 experiencing a high amount of stress. This high stress may damage the turbo pump 210. After the turbo throttle valve 208 is opened to the first position, the turbo throttle valve 208 is further opened to a second position. The second position causes the one or more gases flowing through the turbo throttle valve 208 to flow at a second flow rate greater than the first flow rate. In one or more embodiments, the turbo throttle valve 208 is further opened until the desired flow rate is achieved. In one or more embodiments, the controller 190 controls the position of the turbo throttle valve 208.

At operation 310 a turbo operation is performed. During the turbo operation the one or more gases flow from the processing volume 126 through the turbo assembly 200 and into the vacuum pump 118. In one or more embodiments, the pressure of the processing volume 126 during the turbo operation is less than or equal to 1 Torr, such as less than or equal to 500 mTorr, such as less than or equal to 100 mTorr. In one or more embodiments, the flow rate of the one or more gases flowing through the turbo assembly 200 is less than or equal to about 3 SLM, such as about 2.5 SLM. In one or more embodiments, the turbo operation is performed for a time of 100 seconds or less, such as 90 seconds or less. In one or more embodiments, the turbo operation is performed for a limited time in order to prevent the turbo pump 210 from being damaged and/or burned out. In one or more embodiments, operation 310 is performed by the controller 190.

At operation 312 the turbo throttle valve 208 and the turbo gate valve 212 are closed. The turbo gate valve 212 is closed after the turbo throttle valve 208 is closed. In one or more embodiments, the one or more gases within the turbo pump 210 are exhausted prior to the turbo gate valve 212 being closed. In one or more embodiments, operation 312 is performed by the controller 190.

At optional operation 314 the exhaust gate valve 220 is opened. In one or more embodiments, after the exhaust gate valve is opened, one or more gases within the processing volume 126 flow from the processing volume, through the exhaust line 123, and into the vacuum pump 118. In one or more embodiments, operation 314 is performed by the controller 190.

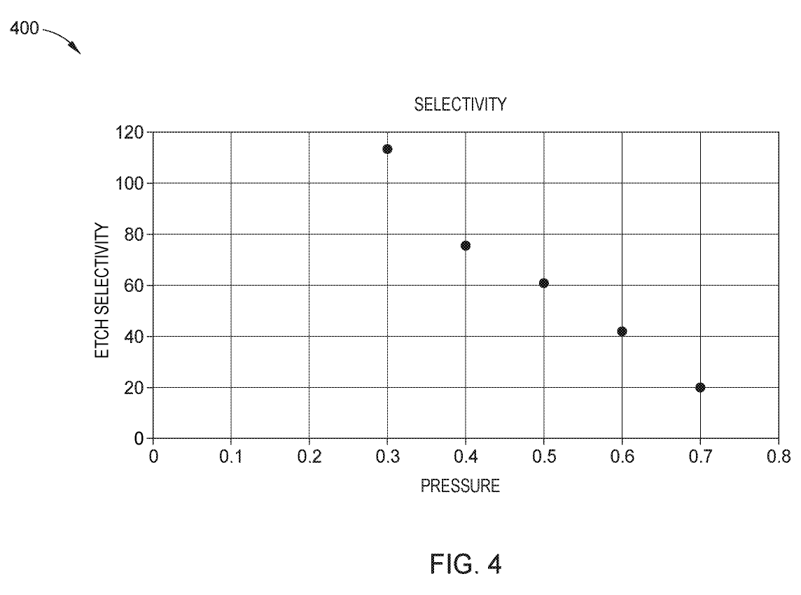

FIG. 4 is a schematic representation of a graph 400, according to one or more embodiments. The graph 400 shows the etch selectivity of one or more etchant gases within the processing volume 126 as the pressure within the processing volume 126 increases, according to one or more embodiments. In one or more embodiments, the etch selectivity is defined by the ratio of the amount of oxide etched by the one or more gases to the amount of silicon nitride etched by the one or more gases. In one or more embodiments, as the pressure within the processing volume 126 decreases, the etch selectivity of the one or more gases increases. During an etch operation, a substrate including a silicon nitride film is disposed within the processing volume 126. One or more gases are flowed within the process volume 126 in order to etch an oxide film formed over the substrate. In one or more embodiments, as the pressure within the processing volume 126 decreases, the etch rate of the oxide and the etch rate of the silicon nitride both decrease. However the etch rate of the silicon nitride decreases at a faster rate than the etch rate of the oxide. Therefore the etch selectivity increases as the overall etch rate decreases. As the etch selectivity increases the ratio of the amount of oxide film removed compared to the amount of silicon nitride film removed increases. A high etch selectivity may improve the overall quality of the film disposed over the substrate. In one or more embodiments, operation 310 of the method 300 is performed during the etch process in order to lower the pressure within the processing volume 126, which improves the etch selectivity. In addition to the improved etch selectivity, the low pressure within the processing volume 126 allows for a faster desorption of byproducts in one or films formed over the substrate, which results in more efficient native oxide etching, including the prevention of reoxidation. Furthermore, in one or more embodiments, the low pressure of the processing volume 126 improves the overall etch conformality across one or more three dimensional features formed over the substrate. The etch conformality is improved because the one or more etchant gases are able to better diffuse across various depths of the one or more three dimensional features.

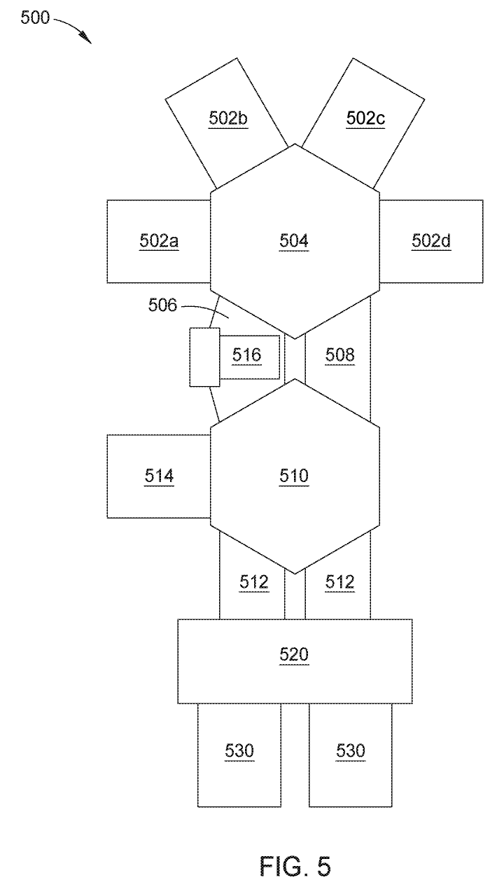

FIG. 5 is a schematic plan view of a system 500, according to one or more embodiments. In one or more embodiments, the system 500 is a cluster tool and/or a vacuum processing system. As shown in FIG. 5, a plurality of processing chambers 502a, 502b, 502c, 502d are coupled to a first transfer chamber 504. The processing chambers 502a-502d may be used to perform any substrate related processes, such as annealing, chemical vapor deposition, physical vapor deposition, epitaxial process, etching process, thermal oxidation or thermal nitridation process, degassing, etc. In one or more embodiments, the processing chamber 502a may be a film formation chamber, such as a vapor phase epitaxy deposition chamber, for example an Epi chamber available from Applied Materials, Santa Clara, California, that is capable of forming a crystalline silicon or silicon germanium. In one or more embodiments, the processing chamber 502a may be an epitaxy deposition chamber such as a single-substrate processing chamber.

The processing chamber 502b may be a rapid thermal processing chamber (RTP). The processing chamber 502c may be a plasma etching chamber or a plasma cleaning chamber. For example the processing chamber 502c may be the processing chamber 100 described in connection with FIGS. 1 and 2. The processing chamber 502d may be a degassing chamber. The first transfer chamber 504 is also coupled to at least one transition station, for example a pair of pass-through stations 506, 508. The pass-through stations 506, 508 maintain vacuum conditions while allowing substrates to be transferred between the first transfer chamber 504 and a second transfer chamber 510. The first transfer chamber 504 has a robotic substrate handling mechanism for transferring substrates between the pass-through stations 506, 508 and any of the processing chambers 502a-502d. The processing chambers 502a-502d are shown configured in a certain order in FIG. 5, but the processing chambers 502a-502d may be configured in any desired order.

One end of the pass-through stations 506, 508 is coupled to the second transfer chamber 510. Therefore, the first transfer chamber 504 and the second transfer chamber 510 are separated and connected by the pass-through stations 506, 508. The second transfer chamber 510 is coupled to a first plasma-cleaning chamber 514, which can be a plasma chamber such as the processing chamber 100 (FIGS. 1 and 2) that is adapted to perform at least some of the operations found in method 300 for removing oxides from a surface of a substrate. In one or more embodiments, the first plasma-cleaning chamber 514 is a Siconi^{TM} or Selectra^{TM} chamber, which is available from Applied Materials, Santa Clara, California.

In one or more embodiments, the at least one transition station, for example one of the pass-through stations 506, 508, is configured to be a plasma-cleaning chamber. Alternatively, a plasma-cleaning chamber may be coupled to one of the pass-through stations 506, 508 for removing contaminants from the surface of the substrate. Thus, the processing system 500 may have a second plasma-cleaning chamber that is, or is connected to, one of the pass-through stations 506, 508. In the implementation shown in FIG. 5, the pass-through station 506 includes a second plasma-cleaning chamber 516. The second plasma-cleaning chamber 516 may be a version of the processing chamber 100 (FIGS. 1 and 2) that is adapted to perform at least some of the operations found in method 300 for removing contaminants from the surface of the substrate. It should be noted that, although one plasma-cleaning chamber 516 is shown coupled to a pass-through station, in this case the pass-through station 506, a plasma-cleaning chamber (e.g., a version of the processing chamber 100) may be coupled to both the pass-through stations 506 and 508.

The second transfer chamber 510 also has a robotic substrate handling mechanism for transferring substrates between a set of load lock chambers 512 and the first plasma-cleaning chamber 514 or the second plasma-cleaning chamber 516. A factory interface 520 is connected to the second transfer chamber 510 by the load lock chambers 512. The factory interface 520 is coupled to one or more pods 530 on the opposite side of the load lock chambers 512. The pods 530 typically are front opening unified pods (FOUP) that are accessible from a clean room.

While two transfer chambers are shown, it is contemplated that any of the transfer chambers may be omitted. In one or more embodiments where the second transfer chamber 510 is omitted, the second plasma-cleaning chamber 516 may be disposed within or coupled to the first transfer chamber 504 at the location currently shown as occupied by the pass-through stations 506 or 508. The first transfer chamber 504 may be coupled to one or more processing chambers capable of forming crystalline silicon or silicon germanium, such as an epitaxy chamber, for example a Centura^{TM} Epi chamber available from Applied Materials, Inc., of Santa Clara, California. Alternatively, the first transfer chamber 504 may be omitted and the second plasma-cleaning chamber 516 may be disposed within or coupled to the pass-through station 506, which is coupled to the second transfer chamber 510. In such a case, the second transfer chamber 510 may be configured to be coupled to one or more processing chambers capable of forming crystalline silicon or silicon germanium.

In operation, substrates are carried from pods 530 to the vacuum processing system 500 in a transport cassette that is placed within one of the load lock chambers 512. The robotic transport mechanism within the second transfer chamber 510 transports the substrates, one at a time, from the load lock chambers 512 to the first plasma-cleaning chamber 514 where the cleaning process, e.g., operations of the method 300, is performed to remove oxides from a surface of a substrate. Once the oxides have been removed from the substrate surface, the robotic transport mechanism disposed within the second transfer chamber 510 transfers the substrate from the first plasma-cleaning chamber 514 to the second plasma-cleaning chamber 516 where a reducing process,e.g., operations of the method 300, is performed to remove contaminants such as carbon or hydrocarbons from the substrate surface. It is contemplated that the steps here may also be performed in the reverse order, e.g., using the robotic transport mechanism to transfer the substrate from the second plasma-cleaning chamber 516 to the first plasma-cleaning chamber 514. In either case, the clean substrates are then transferred by the robotic transport mechanism disposed within the first transfer chamber 504 from the second plasma-cleaning chamber 516 (or the first plasma-cleaning chamber 514) to one or more processing chambers 502a-502d. The one or more processing chambers 502a-502d may include an epitaxy process chamber where a layer formation process, such as the epitaxial deposition is performed.

Upon completion of processing in the one or more processing chambers 502a-502d, the robotic transport mechanism disposed within the first transfer chamber 504 moves the substrate from either one of the processing chambers 502a-502d to the pass-through station 508. The substrate is then removed from the pass-through station 508 by the robotic transport mechanism disposed within the second transfer chamber 510 and transferred to the other load lock chamber 512 through which it is withdrawn from the vacuum processing system 500.

Since the method 300 and/or deposition can be performed within the same system 500, vacuum is not broken as the substrate is transferred among various chambers, which decreases the chance of contamination and improves the quality of the deposited epitaxial film. It should be understood that the movement of the substrates is described herein for illustration purposes. A controller 190 may be used to schedule the movement of the substrates through the vacuum processing system 500 in accordance with a desired sequencing program, which may vary depending upon the application.

Embodiments of the present disclosure include a system and related methods for lowering the pressure of a processing chamber during an etching process. Benefits of performing the etching process in a low pressure environment include increased etch selectivity, increased oxide removal efficiency, and increased film uniformity. Benefits of the increased etch selectivity further include improved film quality, decreased defects, and improved overall device performance.

It is contemplated that one or more aspects disclosed herein may be combined. As an example, one or more aspects, features, components, operations and/or properties of the processing chamber 100, the processing system 101, the lid assembly 104, the vacuum port 122, the controller 190, the vacuum pump 118, the throttle valve 120, the turbo assembly 200, the elbow pipe 204, the turbo throttle valve 208, the turbo pump 210, the turbo gate valve 212, the first pressure gauge 214, exhaust gate valve 220, the second pressure gauge 222, the method 300, the graph 400, and or the system 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing system comprising:
a processing chamber comprising a processing volume;
a vacuum pump fluidly connected to the processing volume; and
a turbo assembly fluidly connected to the processing volume, the turbo assembly comprising:
a turbo throttle valve;
a turbo pump; and
a turbo gate valve.

2. The processing system of claim 1 further comprising:
an exhaust line extending between the processing volume and the vacuum pump, the exhaust line comprising an exhaust gate valve and a throttle valve.

3. The processing system of claim 2, further comprising a first pressure gauge and a second pressure gauge, wherein the first pressure gauge is disposed downstream of the turbo pump and the second pressure gauge is disposed downstream of the throttle valve.

4. The processing system of claim 1, wherein the turbo pump has a pumping speed of 1.6 kiloliters per second.

5. The processing system of claim 1, further comprising one or more gas sources fluidly connected to the processing volume.

6. The processing system of claim 1, further comprising a controller comprising instructions that cause a plurality of operations to be conducted, the plurality of operations comprising:
performing a turbo operation comprising flowing one or more gases from the processing volume through the turbo assembly into the vacuum pump.

7. The processing system of claim 6, wherein the turbo operation comprises flowing the one of more gases through the turbo assembly at a flow rate less than or equal to about 3 SLM.

8. The processing system of claim 6, wherein an internal pressure of the processing volume during the turbo operation is less than or equal to about 1 Torr.

9. The processing system of claim 6, wherein the turbo operation is performed for a time of about 100 seconds or less.

10. A method of substrate processing comprising:
performing an exhaust operation comprising flowing one or more gases within a processing volume of a processing chamber through an exhaust line to a vacuum pump;
closing an exhaust gate valve disposed within the exhaust line;
opening a turbo gate valve disposed within a turbo assembly in fluid communication with the processing volume;
opening a turbo throttle valve disposed within the turbo assembly; and
performing a turbo operation comprising flowing the one or more gases from the processing volume though the turbo assembly to the vacuum pump.

11. The method of claim 10, wherein performing the turbo operation comprises flowing the one of more gases through the turbo assembly at a flow rate less than or equal to about 3 SLM.

12. The method of claim 10, wherein an internal pressure of the processing volume during the turbo operation is less than or equal to about 1 Torr.

13. The method of claim 10, wherein the turbo operation is performed for a time of about 100 seconds or less.

14. The method of claim 10, wherein the turbo assembly comprises a turbo pump having a pumping speed of 1.6 kiloliters per second.

15. The method of claim 10, wherein the turbo throttle valve is opened gradually.

16. A controller comprising instructions that cause a plurality of operations to be conducted, the plurality of operations comprising:
performing an exhaust operation comprising:
flowing one or more gases within a processing volume of a processing chamber through an exhaust line to a vacuum pump;
closing an exhaust gate valve disposed within the exhaust line;
opening a turbo gate valve disposed within a turbo assembly in fluid communication with the processing volume;
opening a turbo throttle valve disposed within the turbo assembly; and
performing a turbo operation comprising:
flowing the one or more gases from the processing volume though the turbo assembly to the vacuum pump.

17. The controller of claim 16, wherein performing the turbo operation comprises flowing the one of more gases through the turbo assembly at a flow rate less than or equal to about 3 SLM.

18. The controller of claim 16, wherein an internal pressure of the processing volume during the turbo operation is less than or equal to about 1 Torr.

19. The controller of claim 16, wherein the turbo operation is performed for a time of about 100 seconds or less.

20. The controller of claim 16, wherein the turbo assembly comprises a turbo pump having a pumping speed of 1.6 kiloliters per second.
